(19) United States
(12) Patent Application Publication
(10) Pub. No.: US 2007/0119566 A1
(43) Pub. Date: May 31, 2007

(54) HEAT DISSIPATION DEVICE

(76) Inventor: Xue-Wen Peng, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,594

(22) Filed: Nov. 30, 2005

(51) Int. Cl. H05K 7/20

(52) U.S. Cl. 165/80.3; 165/104.33; 361/700; 361/697

(57) ABSTRACT

A heat dissipation device includes a fin set including a plurality of fins assembled together and a fan located beside the fin set. Pluralities of air passages are defined between the fins. Each fin has two spaced flaps extending from a main body thereof and dividing the main body to upper and lower portions and a middle portion between the two flaps. The middle portion has a converging entrance between two corresponding end sections of the two flaps. The fan confronts to the air passages and the converging entrances of the middle portions of the fins of the fin set.

### FIELD OF THE INVENTION

The present invention relates generally to a heat dissipation device, and more particularly to a heat dissipation device used for dissipating heat generated by an electronic device.

### DESCRIPTION OF RELATED ART

With advancement of computer technology, electronic devices operate rapidly. It is well known that the more rapidly the electronic devices operate, the more heat they generate. If the heat is not dissipated duly, the stability of the operation of the electronic devices will be impacted severely. Generally, in order to ensure the electronic device to run normally, a heat dissipation device is used to dissipate the heat generated by the electronic device.

Conventionally, a heat dissipation device comprises a heat sink which has a base and a plurality of fins arranged on the base. The fins each being a flat sheet are parallel to and spaced from each other. Therefore, pluralities of passages are defined between the fins for airflow passing therethrough. Usually, the heat dissipation device further comprises a fan located at a side of the heat sink for providing forced airflow to the heat sink. Generally, the fan has a central hub region which is confronted to a middle portion of fins of the heat sink, and a peripheral fan blade region which is confronted to side portions of the fins of the heat sink. When the fan works, the hub region produces a small quantity and low pressure of airflow to the middle portion of the fins, while the blade region produces a large quantity and high pressure of airflow to the side portions of the fins. Therefore, the middle portion of the fins has a very limited amount of airflow passing therethrough, while the side portions of the fins have an excessive amount of airflow passing therethrough. That is to say, the amounts of airflow distribute on the fins unevenly due to a configuration of the fan. Due to such uneven airflow distribution the middle portion of the fins always has too much heat accumulated therein, which can not dissipated away effectively. Accordingly, the heat dissipation capacity of the conventional heat dissipation device is not optimal. It is necessary to improve the heat dissipation capacity of the conventional heat dissipation device.

What is needed, therefore, is a heat dissipation device having improved heat dissipation capacity.

### SUMMARY OF INVENTION

A heat dissipation device in accordance with a preferred embodiment of the present invention comprises a fin set comprising a plurality of fins assembled together and a fan located beside the fin set. Pluralities of passages are defined between the fins. The fan faces the passages. Each fin has two spaced flaps extending from a main body thereof and dividing the main body generally into upper, middle and lower portions. The two flaps have middle sections extending parallel to each other, and end sections extending away from each other whereby the end sections of the flaps located close to the fan form a converging inlet facing the fan, and the end sections of the flaps located distant from the fan form a diverging outlet opposing the fan. The inlets and outlets are used for guiding an airflow generated by the fan to flow through the middle portions of the fins. The fan confronts to the passages and the converging inlets of the middle portions of the fins of the fin set. By such design, a larger amount of airflow can be guided by the converging inlets to flow into the middle portions of the fins and by the diverging outlets to leave the middle portions of the fins.

Other advantages and novel features will become more apparent from the following detailed description of preferred embodiments when taken in conjunction with the accompanying drawings, in which:

### BRIEF DESCRIPTION OF DRAWINGS

FIG. 1 is an exploded, isometric view of a heat dissipation device in accordance with a preferred embodiment of the present invention;

FIG. 2 shows a fin of the heat dissipation device of FIG. 1; and

FIG. 3 is a assembled view of FIG. 1.

### DETAILED DESCRIPTION

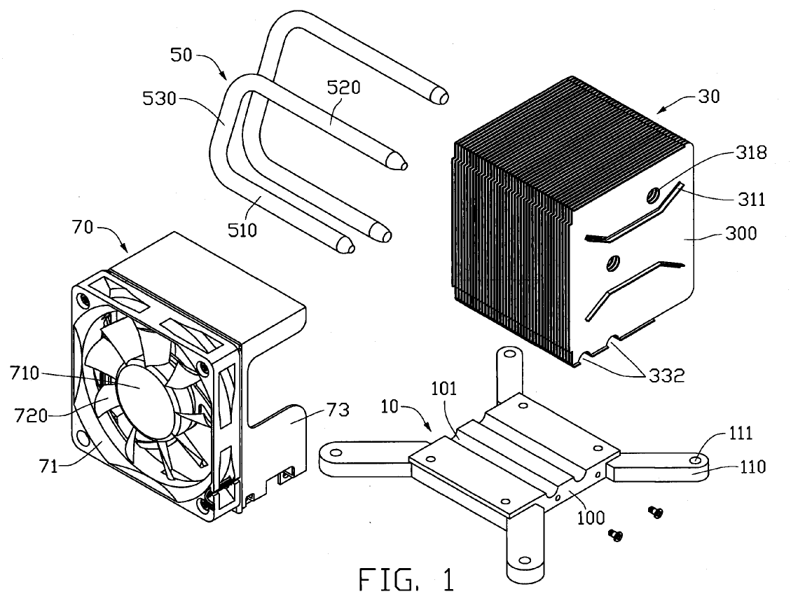

Referring to FIG. 1, a heat dissipation device in accordance with a preferred embodiment of the present invention comprises a heat sink having a base 10 and a fin set 30 on the base 10, two heat pipes 50 connecting the base 10 and the fin set 30, and a fan unit 70 mounted beside the fin set 30.

The base 10 comprises a substantially rectangular heat receiver 100, and four fixing legs 110 extending outwardly from four corners of the heat receiver 100. The heat receiver 100 has a good heat conductivity. A top face of the heat receiver 100 defines therein two parallel grooves 101 each with a semicircular cross-section. A bottom face of the heat receiver 100 is flat for thermally contacting a heat generating electronic device (not shown) mounted on a printed circuit board (not shown). Each of the fixing legs 110 defines a fixing hole 111 in a distal end thereof for fixing the heat dissipation device to the printed circuit board.

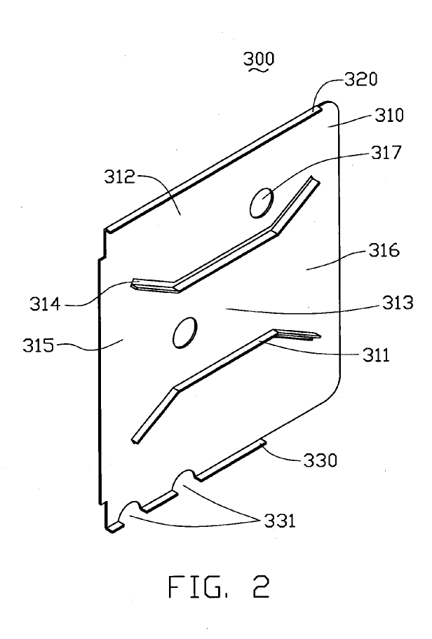

Referring also to FIG. 2, the fin set 30 comprises a plurality fins 300 assembled together. Each fin 300 comprises a main body 310, a first flange 320 perpendicularly extending from a top edge of the main body 310, and a second flange 330 perpendicularly extending from a bottom edge of the main body 310. The bottom edge of the main body 310 defines two semicircular cutouts 331 therein. The cutouts 331 are located corresponding to the grooves 101 of the heat receiver 100. Two spaced flaps 311 are stamped from the main body 310 substantially along a direction parallel to the two flanges 320, 330, whereby two slits 314 are defined in the main body 310 of the fin 300 adjacent to the flaps 311 respectively. The two flaps 311 divide the main body 310 into three portions: two side portions (i.e., upper and lower portions) 312 respectively between the flanges 320, 330 and the corresponding flaps 311, and a middle portion 313 between the two flaps 311. Each of the flaps 311 has a middle section (not labeled), a front end section (not labeled) and a rear end section (not labeled). The middle sections are parallel to each other. The front end sections extend from the middle sections in directions away from each other. The rear end sections extend from the middle sections in directions away from each other. The front end sections of the flaps 311 form a converging entrance 315 for the middle portion 313. The rear end sections form a diverging exit 316 for the middle portion 313. Two holes 317 are defined in the main body 310, one of which is located between the two flaps 311, and another of which is located above an upper one of the two flips 311. In assembly, the flanges 320, 330 of each fin 300 abut the top and bottom edges of the main body 310 of an adjacent fin 300 respectively. The cutouts 331 of the fins 300 corporately define two slots 332 each with a semicircular cross-section. The holes 317 of the body 100 of the fins 300 corporately define two through channels 318 extending through the fin set 30 for receiving the heat pipes 50. Pluralities of air passages (not labeled) are defined between the fins 300 and extend from front sides to rear sides thereof.

Each of the two heat pipes 50 is U-shaped, and comprises a first heat transfer section (i.e., evaporating section) 510, a second heat transfer section (i.e., condensing section) 520 parallel to the first heat transfer section 510, and a middle section connecting with the first and second heat transfer sections 510, 520 at ends thereof. A round corner is formed at each joint of the first, middle and second sections 510, 530, 520.

The fan unit 70 comprises a fan 71 and a fan bracket 73 for fixing the fan 71 to the fin set 30. The fan 71 comprises a hub 710 and a plurality of fan blades 720 radially extends from the hub 710. The bracket 73 comprises four interconnecting walls (not labeled) having fixing members (not labeled) formed thereon.

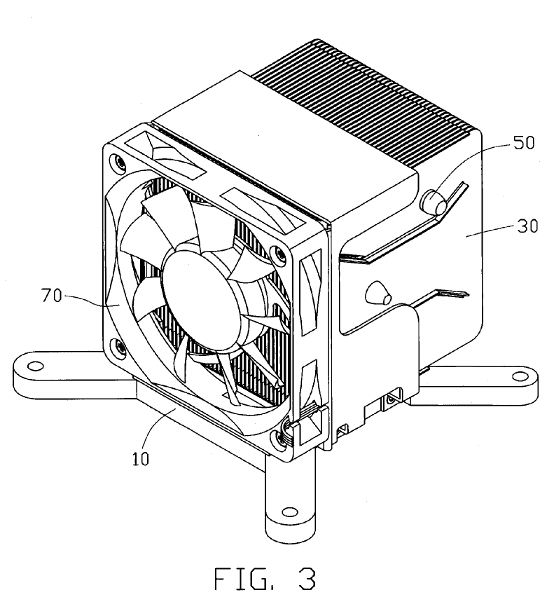

Referring also to FIG. 3, in assembly, the fin set 30 is combined to the heat receiver 100 of the base 10 by conventional means such as soldering, adhering and so on. The second flanges 330 of the fins 100 thermally contact with the top face of the heat receiver 100. The first heat transfer sections 510 of the two heat pipes 50 are thermally received in two passages (not labeled) corporately defined by the two grooves 101 of the heat receiver 100 and the two slots 332 of the fin set 30. The second heat transfer sections 330 of the heat pipes 50 are respectively thermally received in the two through channels 318 of the fin set 30. The fan unit 70 is attached to a front side of the fin set 30 via the fixing members of the bracket 73 engaged with the fin set 30 and the base 10. The fan 71 faces the air passages between the fins 300 and the entrances 315 of the middle portions 313 of the fins 300 of the fin set 30.

In use, the heat receiver 100 of the base 10 absorbs heat generated by the heat generating electronic device (not shown) with which the heat receiver 100 contacts. The heat in the heat receiver 100 is then transferred to a bottom portion of the fin set 30 and the first heat transfer sections 510 of the heat pipes 50. The heat in the first heat transfer sections 510 of the heat pipes 50 is subsequently transferred to the second heat transfer sections 520 via the middle sections 530 of the heat pipes 50, and then reaches the fins 300. The heat in the fin set 30 is dissipated to ambient air duly under the action of an airflow generated by the fan 71.

According to the preferred embodiment of the present invention, each of the fins 300 of the fin set 30 is divided to three portions by the two flaps 311. The middle portion 313 has the converging entrance 315 confronted to the fan 71; therefore, a large portion of the airflow generated by the fan 71 is collected by the front end sections of the flaps 311 to enter the middle portions 314 of the fins 300 to remove heat in the middle portions 313. Furthermore, due to the diverging exits 316, the hot air in the middle portions 313 of the fins 300 can quickly leave the middle portions 313. Therefore, in comparison with the conventional heat dissipation devices, the fins 300 of the present invention can distribute the airflow from the fan 71 on the fins 300 more evenly. The heat in the middle portions 313 of the fins 300 can be dissipated to the ambient air more duly and quickly. Thus, heat dissipation capacity of the heat dissipation device in accordance with the present invention is improved. The heat dissipation capacity of the heat dissipation device in accordance with the present invention is further improved by the provision of the slits 314, which enable neighboring air channels to communicate with each other. Accordingly, the heat on the fin set 30 can leave the fin set 30 not only along a front-to-rear direction, but also along a lateral direction of the fin set 30.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a fin set comprising a plurality of fins assembled together, each of the fins having two spaced flaps extending from a main body thereof and dividing the main body into two side portions and a middle portion between the two side portions and the two flaps, the middle portion having a converging entrance between corresponding end sections of the two flaps; and
a fan being located beside the fin set and confronting the entrances of the middle portions of the fins of the fin set.

2. The heat dissipation device of claim 1, wherein the two flaps are stamped from the main body of each of the fins, whereby two slits are defined in the main body adjacent to the two flaps, respectively.

3. The heat dissipation device of claim 1, wherein the middle portion of each of the fins has a diverging exit opposite the entrance, the exit being defined between other corresponding end sections of the two flaps of the middle portion.

4. The heat dissipation device of claim 1, wherein the two flaps respectively extend along a direction generally parallel to two opposite edges of the main body of each of the fins.

5. The heat dissipation device of claim 4, wherein the end sections of the two flaps extend toward corresponding edges of the two opposite edges of the main body of each of the fins, respectively.

6. The heat dissipation device of claim 1, wherein each of the fins has two flanges generally perpendicularly extending from two opposite edges of the main body thereof.

7. The heat dissipation device of claim 6 further comprising a heat pipe, wherein the fin set has a slot defined in a bottom portion thereof, and wherein a portion of the heat pipe is received in the slot.

8. The heat dissipation device of claim 7, wherein the fin set defines a channel extending through each fin of the fin set, and wherein another portion of the heat pipe is received in the channel.

9. The heat dissipation device of claim 8 further comprising a base, wherein the fin set is thermally combined to the base.

10. The heat dissipation device of claim 9, wherein the a top of the base defines a groove corresponding to the slot of the fin set, and wherein the portion of the heat pipe is received in a passage corporately defined by the groove and the slot.

11. The heat dissipation device of claim 1 further comprising a bracket attached to the fin set, wherein the fan is attached to the bracket.

12. A heat dissipation device comprising:
a fin set comprising a plurality of fins assembled together, a plurality of air passages being defined between the fins, each of the fins having two spaced flaps extending from a main body thereof, whereby a portion between the two flaps is defined in a middle of the main body, the two flaps having two corresponding end sections thereof extending outwardly, thereby the portion having a converging entrance defined between the two corresponding end sections of the two flaps; and
a fan facing the air passages and the converging entrances of the portions of the fins of fin set.

13. The heat dissipation device of claim 12, wherein the two flaps are stamped form the main body of the fin, whereby two slits are defined in the main body adjacent to the two flaps, respectively.

14. The heat dissipation device of claim 12, wherein each of the fins has two flanges extending from two opposite edges of the main body thereof.

15. The heat dissipation device of claim 12 further comprising a heat pipe, wherein the heat pipe is thermally combined to the fin set.

16. The heat dissipation device of claim 15 further comprising a base, wherein the heat pipe thermally connects the base and the fin set.

17. A heat dissipation device comprising:
a fin set comprising a plurality of fins connected together, a plurality of air passages being defined between the fins and extending from a front side to a rear side thereof, each fin forming two flaps thereon to divide the fin into upper portion, middle portion and lower portion, the flaps being configured to form a converging entrance for the middle portion, said converging entrance facing the front side of the fin set; and
a fan located at the front side of the fin set and generating an air flow toward the air passages of the fin set.

18. The heat dissipation device of claim 17, wherein the flaps are configured to form a diverging exit for the middle portion, the diverging exit facing the rear side of the fin set.

19. The heat dissipation device of claim 18, wherein said each fin defines two slits adjacent the two flaps, respectively.

20. The heat dissipation device of claim 19 further comprising a heat pipe having an evaporating section thermally connecting with a bottom of the fin set and a condensing section inserted in the middle portions of the fins of the fin set.
